(19) United States
(12) Patent Application Publication
(10) Pub. No.: US 2026/0182153 A1
(43) Pub. Date: Jun. 25, 2026

(54) DISPLAY DEVICE AND ELECTRONIC DEVICE INCLUDING THE DISPLAY DEVICE

(71) Applicant: Samsung Display Co., LTD., Yongin-si (KR)

(72) Inventors: Hyoung Sik KIM, Yongin-si (KR); Jong Hee PARK, Yongin-si (KR); Woo Jin CHO, Yongin-si (KR)

(21) Appl. No.: 19/303,963

(22) Filed: Aug. 19, 2025

(30) Foreign Application Priority Data
Dec. 19, 2024 (KR) 10-2024-0191248

(51) Int. Cl. H10K 59/122; H10K 59/123; H10K 59/131

(52) U.S. Cl. CPC H10K 59/122; H10K 59/123; H10K 59/131

(57) ABSTRACT

A display device includes a partition wall on a substrate and including a first inclined surface, a connection electrode on the partition wall and including a second inclined surface, a first electrode on the connection electrode, a light-emitting layer on the first electrode, and a second electrode on the light-emitting layer and in contact with the second inclined surface of the connection electrode, wherein the partition wall surrounds the connection electrode in a plane.

This application claims priority to Korean Patent Application No. 10-2024-0191248, filed on Dec. 19, 2024, and all the benefits accruing therefrom under 35 U.S.C. § 119, the content of which in its entirety is herein incorporated by reference.

### BACKGROUND

### 1. Field

Embodiments supported by the present disclosure relates to a display device and an electronic device including the display device.

### 2. Description of the Related Art

With the increasing interest in information displays in recent years, research and development of display devices have been continuously conducted.

### SUMMARY

An object of the present invention is to provide a display device with improved reliability and an electronic device including the display device.

The object of the present invention is not limited to the above-mentioned objects, and other technical objects that are not mentioned will be clearly understood by those skilled in the art from the following description.

According to an embodiment of the present disclosure, there is provided a display device, including: a partition wall on a substrate and including a first inclined surface; a connection electrode on the partition wall and including a second inclined surface; a first electrode on the connection electrode; a light-emitting layer on the first electrode; and a second electrode on the light-emitting layer and in contact with the second inclined surface of the connection electrode, wherein the partition wall surrounds the connection electrode in a plan view.

The display device may further include a connection line on the partition wall.

The connection line may be directly on the partition wall.

The connection line may entirely cover the partition wall.

The display device may further include a connection pattern between the connection line and the connection electrode.

The connection pattern may be electrically connected with the connection line and the connection electrode.

The width of the connection pattern may be less than the width of the connection electrode.

The display device may further include a contact electrode on the substrate and electrically connected to the first electrode.

The display device may further include a first insulating layer on the contact electrode.

The partition wall may be directly on the first insulating layer.

The partition may include a same material as the first insulating layer.

The first electrode may be in contact with the contact electrode through a contact portion which penetrates through the connection electrode.

An electronic device according to an embodiment for solving the above problem includes a processor and a display device including pixels, the display device which displays an image via the pixels under control of the processor, the pixels each including a partition wall on a substrate and including a first inclined surface, a connection electrode on the partition wall and including a second inclined surface, a first electrode on the connection electrode, a light-emitting layer on the first electrode, and a second electrode on the light-emitting layer and in contact with the second inclined surface of the connection electrode, wherein an inclination angle of the first inclined surface is the same as an inclination angle of a second inclined surface.

The inclination angle of the first inclined surface and the inclination angle of the second inclined surface may range from 30° to 60°.

The display device may further include a second insulating layer between the connection electrode and the first electrode.

The second insulating layer may include a third inclined surface.

An inclination angle of the third inclined surface may be the same as the inclination angle of the first inclined surface.

The display device may further include a pixel defining layer surrounding an edge of the first electrode.

The pixel defining layer may include a fourth inclined surface.

An inclination angle of the fourth inclined surface may be the same as the inclination angle of the first inclined surface.

Further details of other embodiments are contained in the description and the drawings.

According to the foregoing embodiments, by forming the inclined surface at the edge of the connection electrode by using the partition wall, the contact area between the connection electrode and the cathode electrode can be increased, thereby reducing the resistance and minimizing the risk of disconnection of the cathode electrode.

Effects according to the embodiments are not limited by the content illustrated above, and more various effects are included in the present specification.

### BRIEF DESCRIPTION OF THE DRAWINGS

FIG. 1 is a block diagram illustrating an embodiment of a display device.

FIG. 2 is a block diagram illustrating an embodiment of any one of the sub-pixels of FIG. 1.

FIG. 3 is a plan view illustrating an embodiment of the display panel of FIG. 1.

FIG. 4 is a top view illustrating an embodiment of the pixel of FIG. 3.

FIGS. 5 and 6 are cross-sectional views illustrating an embodiment of any one of the sub-pixels of FIG. 4.

FIG. 7 is an enlarged cross-sectional view illustrating the region A of FIG. 5.

FIG. 8 is a block diagram illustrating an embodiment of a display system including the display device of FIGS. 1 to 7.

FIG. 9 is a perspective view illustrating an example of a smartphone that can be implemented using the display system of FIG. 8.

FIG. 10 is a perspective view illustrating an example of a tablet computer that can be implemented using the display system of FIG. 8.

FIGS. 11 to 19 are process step-by-step cross-sectional views of a method for manufacturing a display device according to an embodiment.

### DETAILED DESCRIPTION

Hereinafter, example embodiments of the present invention will be described in detail with reference to the accompanying drawings. It should be noted that in the following description, parts for understanding the operation according to the present invention are described, and the description of other parts will be omitted so as not to obscure the gist of the present invention. Aspects supported by the present disclosure are not limited to the embodiments described herein and may be embodied in other forms. Rather, the embodiments described herein are provided such that this disclosure will be readily apparent to those skilled in the art.

Throughout the specification, when a part is referred to as being “connected” to another part, this may include not only “directly connected” but also “indirectly connected” with another element interposed therebetween. The terminology used herein is for the purpose of describing particular embodiments and is not intended to be limiting of the invention. Throughout the specification, when it is stated that a part may “include” a certain component, it may mean that the part may further include the other component without excluding the other component unless there is a particular description to the contrary. “At least one of X, Y, and Z” and “at least one selected from the group consisting of X, Y and Z” can be interpreted as one X, one Y, one Z, or some combination of two or more of X, Y or Z (e.g., XYZ, XYY, YZ, ZZ). Here, “and/or” may include any combination of one or more of the corresponding elements.

Although the terms first, second, and the like may be used herein to describe various elements, these elements are not limited by these terms. These terms may be used to distinguish one component from another. Thus, a first component can refer to a second component without departing from what is disclosed herein.

Spatially relative terms, such as, for example, “below,” “above,” and the like, may be used for descriptive purposes to describe one element or feature's relationship to another element(s) or feature(s) as illustrated in the figures. Spatially relative terms are intended to encompass different orientations in use, operation, and/or manufacture in addition to the orientation depicted in the figures. For example, if the device illustrated in the figures is turned over, elements depicted as being “below” other elements or features may be positioned in a direction “above” the other elements or features. Thus, in an embodiment, the term “below” may encompass both an orientation of above and below. Further, the device may be oriented in other directions (e.g., rotated 90 degrees or in other directions), and thus the spatially relative terms used herein may be interpreted accordingly.

Various embodiments may be described with reference to the drawings, which illustrate example embodiments. Accordingly, it will be appreciated that the shapes may vary depending on, for example, tolerances and/or manufacturing techniques. Thus, embodiments disclosed herein are not to be construed as limited to the particular shapes illustrated, but rather as including changes in shapes that occur, for example, as a result of manufacturing. As such, the shapes illustrated in the figures may not depict actual shapes of regions of the apparatus, and the present embodiments are not limited thereto.

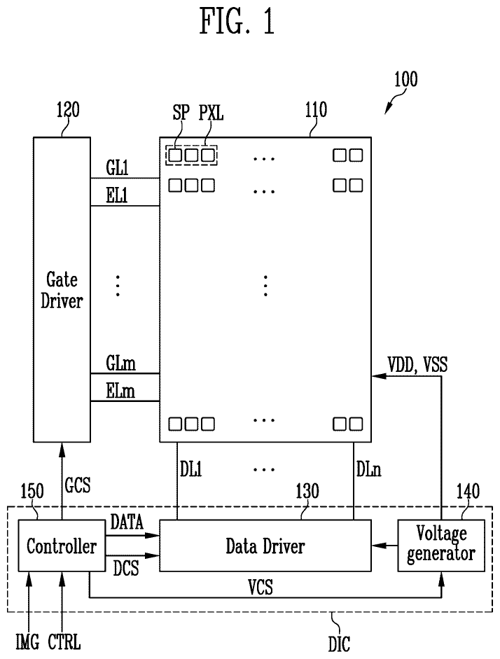

FIG. 1 is a block diagram illustrating an embodiment of a display device.

Referring to FIG. 1, the display device 100 may include a display panel 110, a gate driver 120, a data driver 130, a voltage generator 140, and a controller 150.

The display panel 110 may include sub-pixels SP. The sub-pixels SP may be connected to the gate driver 120 through the first to m-th gate lines GL1 to GLm. The sub-pixels SP may be connected to the data driver 130 through the first to n-th data lines DL1 to DLn.

Each of the sub-pixels SP may include at least one light-emitting element configured to generate light. Accordingly, each of the sub-pixels SP may generate light of a specific color, such as, for example, red, green, blue, cyan, magenta, yellow, or the like. Two or more sub-pixels of the sub-pixels SP may constitute one pixel PXL. For example, as illustrated in FIG. 1, three sub-pixels SP may constitute one pixel PXL.

The gate driver 120 may be connected to the sub-pixels SP arranged in the row direction through the first to m-th gate lines GL1 to GLm. The gate driver 120 may output gate signals to the first to m-th gate lines GL1 to GLm in response to the gate control signal GCS. In an embodiment, the gate control signal GCS may include a start signal indicating the start of each frame, a horizontal synchronization signal for outputting gate signals in synchronization with the timing at which the data signals are applied, or the like.

In an embodiment, first to m-th light-emitting control lines EL1 to ELm connected to the sub-pixels SP in the row direction may be further provided. In this case, the gate driver 120 may include a light emitting control driver configured to control the first to m-th light emitting control lines EL1 to ELm, and the light emitting control driver may operate according to the control of the controller 150.

The gate driver 120 may be disposed on one side of the display panel 110. However, embodiments are not so limited. For example, the gate driver 120 may be divided into two or more drivers that are physically and/or logically separated, and such drivers may be disposed on one side of the display panel 110 and the other side of the display panel 110 opposite to the one side. As such, the gate driver 120 may be disposed at the periphery of the display panel 110 in various forms according to embodiments.

The data driver 130 may be connected to the sub-pixels SP arranged in the column direction through the first to n-th data lines DL1 to DLn. The data driver 130 may receive the image data DATA and the data control signal DCS from the controller 150. Data driver 130 may operate in response to a data control signal (DCS). In an embodiment, the data control signal DCS may include a source start pulse, a source shift clock, a source output enable signal, or the like.

The data driver 130 may apply, using voltages from the voltage generator 140, data signals including grayscale voltages corresponding to the image data DATA to the first to n-th data lines DL1 to DLn. In an example in which a gate signal is applied to each of the first to m-th gate lines GL1 to GLm, data signals corresponding to the image data DATA may be applied to the data lines DL1 to DLm. Corresponding sub-pixels SP can thus generate light corresponding to the data signals. Thus, an image can be displayed on the display panel 110.

In an embodiment, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to components of the display device 100. For example, the voltage generator 140 may be configured to generate a plurality of voltages by receiving an input voltage from the outside of the display device 100, adjusting the received voltage, and regulating the adjusted voltage.

The voltage generator 140 may generate a first power supply voltage VDD and a second power supply voltage VSS, and the generated first and second power supply voltages VDD and VSS may be provided to the sub-pixels SP. The first power supply voltage VDD may have a relatively high voltage level, and the second power supply voltage VSS may have a lower voltage level than the first power supply voltage VDD. In another embodiment, the first power supply voltage VDD or the second power supply voltage VSS may be provided by an external device of the display device 100.

In some aspects, the voltage generator 140 may generate various voltages. For example, the voltage generator 140 may generate an initialization voltage that is applied to the sub-pixels SP For example, in a sensing operation for sensing electrical characteristics of transistors and/or light-emitting elements of the sub-pixels SP, a predetermined reference voltage may be applied to the first to n-th data lines DL1 to DLn, and the voltage generator 140 may generate such a reference voltage.

The controller 150 can control various operations of the display device 100. The controller 150 may receive the input image data IMG and the control signal CTRL for controlling display of the display device 100 from the outside. The controller 150 may provide the gate control signal GCS, the data control signal DCS, and the voltage control signal VCS in response to the control signal CTRL.

The controller 150 may convert the input image data IMG to be suitable for the display device 100 or the display panel 110 and output the image data DATA. In an embodiment, the controller 150 may output the image data DATA by aligning the input image data IMG to fit the sub-pixels SP in units of rows.

Two or more components of the data driver 130, the voltage generator 140, and the controller 150 may be mounted in one integrated circuit. As illustrated in FIG. 1, data driver 130, voltage generator 140, and controller 150 may be included in a driver integrated circuit (DIC). In this case, data driver 130, voltage generator 140, and controller 150 may be functionally distinct components within one driver integrated circuit (DIC). In other embodiments, at least one of the data driver 130, the voltage generator 140, and the controller 150 may be provided as a component separate from a driver integrated circuit (DIC).

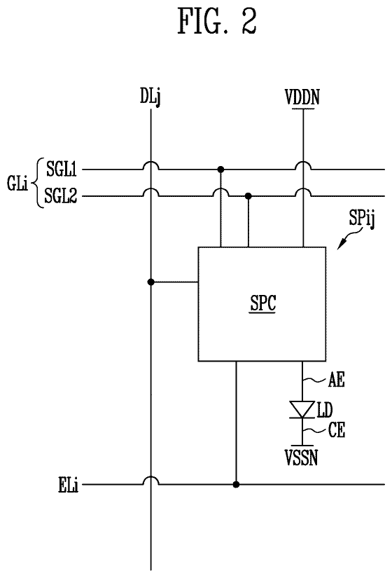

FIG. 2 is a block diagram illustrating an embodiment of any one of the sub-pixels of FIG. 1. In FIG. 2, a sub-pixel SPij arranged in an i-th row (i is an integer greater than or equal to 1 and less than or equal to m) and a j-th column (j is an integer greater than 1 and less than n) of the sub-pixels SP in FIG. 1 is illustrated as an example.

Referring to FIG. 2, the sub-pixel SPij may include a sub-pixel circuit SPC and a light-emitting element LD.

The light-emitting element LD may be connected between the first power supply voltage node VDDN and the second power supply voltage node VSSN. The first power supply voltage node VDDN may be a node that delivers the first power supply voltage VDD of FIG. 1, and the second power supply voltage node VSSN may be a nodes that delivers the second power supply potential VSS of FIG. 1.

The anode electrode AE of the light-emitting element LD may be connected to the first power supply voltage node VDDN through the sub-pixel circuit SPC, and the cathode electrode CE of the light-emitting element LD may be coupled to the second power supply voltage node VSSN. For example, the anode electrode AE of the light-emitting element LD may be connected to the first power supply voltage node VDDN through one or more transistors included in the sub-pixel circuit SPC.

The sub-pixel circuit SPC may be connected to an i-th gate line GLi of the first to m-th gate lines GL1 to GLm in FIG. 1, an i-th light-emitting control line ELi of the first to M-th light-emitting control lines EL1 to ELm in FIG. 1 and a j-th data line DLj of the first to n-th data lines DL1 to DLn in FIG. 1. The sub-pixel circuit SPC may be configured to control the light-emitting element LD in accordance with signals received through these signal lines.

The sub-pixel circuit SPC may operate in response to a gate signal received through the i-th gate line GLi. The i-th gate line GLi may include one or more sub-gate lines. In an embodiment, as illustrated in FIG. 2, the i-th gate line GLi may include first and second sub-gate lines SGL1, SGL2. The sub-pixel circuit SPC may operate in response to gate signals received through the first and second sub-gate lines SGL1, SGL2. Thus, in the case where the i-th gate line GLi includes two or more sub-gate lines, the sub-pixel circuit SPC can operate in response to gate signals received through the sub-gate lines.

The sub-pixel circuit SPC may operate in response to a light-emitting control signal received via the i-th light-emitting control line ELi. In an embodiment, the i-th light-emitting control line ELi may include one or more sub-light-emitting control lines. In an example in which the i-th light-emitting control line ELi includes two or more sub-light-emitting control lines, the sub-pixel circuit SPC may operate in response to light-emitting control signals received through the sub-light-emitting control lines.

The sub-pixel circuit SPC can receive a data signal through the j-th data line DLj. The sub-pixel circuit SPC may store a voltage corresponding to the data signal in response to at least one of the gate signals received via the first and second sub-gate lines SGL1, SGL2. The sub-pixel circuit SPC may adjust the current flowing from the first power supply voltage node VDDN to the second power supply voltage node VSSN through the light-emitting element LD according to the stored voltage, in response to the light-emitting control signal received through the i-th light-emitting control line ELi. Thus, the light-emitting element LD can generate light with a luminance corresponding to the data signal.

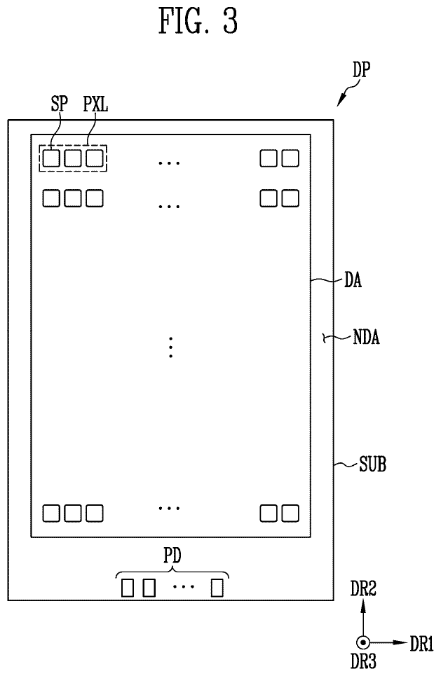

FIG. 3 is a plan view illustrating an embodiment of the display panel of FIG. 1.

Referring to FIG. 3, an embodiment of the display panel 110/DP of FIG. 1 may include a display area DA and a non-display area NDA. The display panel DP can display an image through the display region DA. The non-display area NDA may be disposed in the periphery of the display area DA.

The display panel DP may include a substrate SUB, sub-pixels SP, and pads PD.

The sub-pixels SP may be disposed in the display region DA on the substrate SUB. The sub-pixels SP may be arranged in a matrix form along a first direction DR1 and a second direction DR2 intersecting the first direction DR1. However, embodiments are not so limited. For example, the sub-pixels SP may be arranged in a zigzag pattern along the first direction DR1 and the second direction DR2. For example, the sub-pixels SP may be arranged in a pentile form. The first direction DR1 may be a row direction, and the second direction DR2 may be a column direction.

Two or more sub-pixels of the plurality of sub-pixels SP may constitute one pixel PXL.

In the non-display region NDA on the substrate SUB, a component for controlling the sub-pixels SP can be placed. For example, wirings connected to the sub-pixels SP such as, for example, the first to m-th gate lines GL1 to GLm and the first to n-th data lines DL1 to DLn in FIG. 1 can be disposed in the non-display region NDA.

At least one of the gate driver 120, the data driver 130, the voltage generator 140, and the controller 150 in FIG. 1 can be integrated into the non-display region NDA of the display panel DP In an embodiment, the gate driver 120 in FIG. 1 may be mounted on the display panel DP and disposed in the non-display area NDA. In another embodiment, the gate driver 120 may be implemented as an integrated circuit separate from the display panel DP.

Pads PD may be disposed in the non-display area NDA on the substrate SUB. The pads PD may be electrically connected to the sub-pixels SP through wirings. For example, the pads PD may be connected to the sub-pixels SP through the first to n-th data lines DL1 to DLn.

The pads PD can interface the display panel DP to other components of the display device 100 (see FIG. 1). In an embodiment, voltages and signals for operation of components included in the display panel DP can be provided from the driver integrated circuit DIC in FIG. 1 through the pads PD. For example, the first to n-th data lines DL1-DLn may be connected to a driver integrated circuit DIC via pads PD. For example, the first and second power supply voltages VDD, VSS may be received from the driver integrated circuit DIC via the pads PD. For example, in the case where the gate driver 120 is mounted on the display panel DP, the gate control signal GCS can be transmitted from the driver integrated circuit DIC to the gate driver 120 through the pads PD.

In an embodiment, a circuit board may be electrically connected to the pads PD by using a conductive adhesive member such as, for example, an anisotropic conductive film. At this time, the circuit board may be a flexible circuit board (FPCB) or a flexible film including a flexible material. A driver integrated circuit (DIC) may be mounted to a circuit board and electrically connected to pads (PD).

In an embodiment, the display region DA may have various shapes. The display region DA may have a shape of a closed loop including straight and/or curved sides. For example, the display region DA can have shapes of a polygon, a circle, a semicircle, an ellipse, and the like.

In the embodiment, the display panel DP may have a flat display surface. In another embodiment, the display panel DP may have an at least partially round display surface. In an embodiment, the display panel DP may be bendable, foldable, or rollable. In such cases, display panel DP and/or substrate SUB may include materials that include flexible properties.

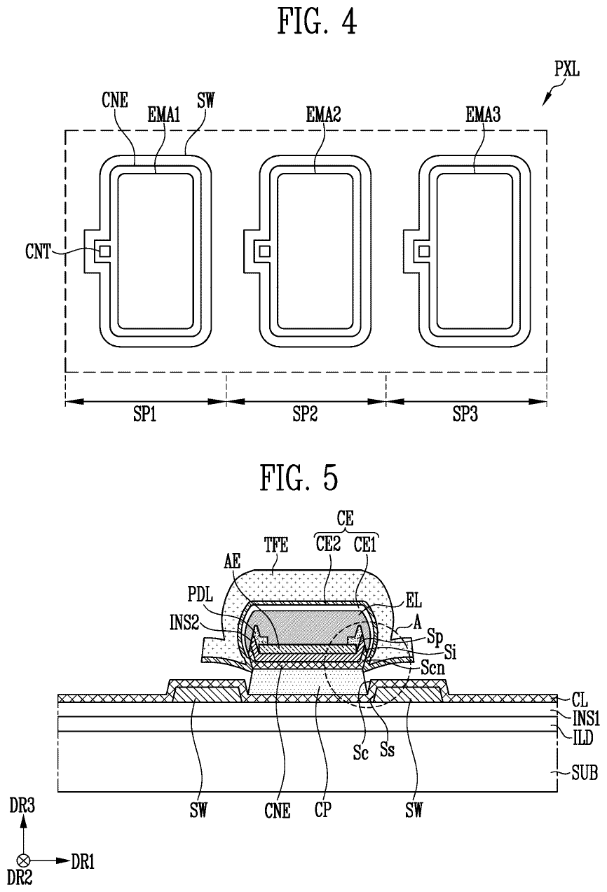

FIG. 4 is a top view illustrating an embodiment of the pixel of FIG. 3.

Referring to FIG. 4, the pixel PXL may include first to third sub-pixels SP1 to SP3 arranged in the first direction DR1.

The first sub-pixel SP1 may include a first light-emitting region EMA1 and a non-light-emitting region NEA around the first light-emitting regions EMA1. The second sub-pixel SP2 may include a second light-emitting area EMA2 and a non-light-emitting area NEA around the second light-emitting areas EMA2. The third sub-pixel SP3 may include a third light-emitting region EMA3 and a non-light-emitting region NEA around the third light-emitting regions EMA3.

The first light-emitting region EMA1 may be a region from which light is emitted from the light-emitting layer corresponding to the first sub-pixel SP1. The second light-emitting region EMA2 may be a region from which light is emitted from the light-emitting layer corresponding to the second sub-pixel SP2. The third light-emitting region EMA3 may be a region from which light is emitted from the light-emitting layer corresponding to the third sub-pixel SP3. The first to third light-emitting regions EMA1 to EMA3 may be understood as openings of the pixel defining layer PDL corresponding to the first to third sub-pixels SP1 to SP3, respectively.

In an embodiment, the pixel PXL may include partition walls SW respectively surrounding the planar connection electrodes CNE. The partition wall SW may be disposed around the connection electrode CNE. In an embodiment, the area of the connection electrode CNE may be larger than the area of the light-emitting regions EMA1 to EMA3, but is not necessarily limited thereto.

In an embodiment, the partition wall SW may include an inclined surface. By the inclined surface of the partition wall SW, an inclined surface can be formed on the connection electrode CNE or the like disposed above the partition wall SW. Accordingly, the contact area of the cathode electrode (see CE in FIG. 5) in contact with the inclined surface of the connection electrode CNE can be increased to reduce resistance and minimize the risk of disconnection of the cathode electrode CE, such that the reliability of the display device can be improved. A detailed description thereof will be given below with reference to FIGS. 5 to 7.

In an embodiment, the partition wall SW may surround the planar light emitting areas EMA1-EMA3. The partition wall SW may be disposed around the light-emitting regions EMA1 to EMA3. As an example, the partition wall SW may be disposed around the contact portion CNT of each of the sub-pixels SP1 to SP3 to surround the contact portion CNS of each of the planar sub-pixels SP1 to SP3.

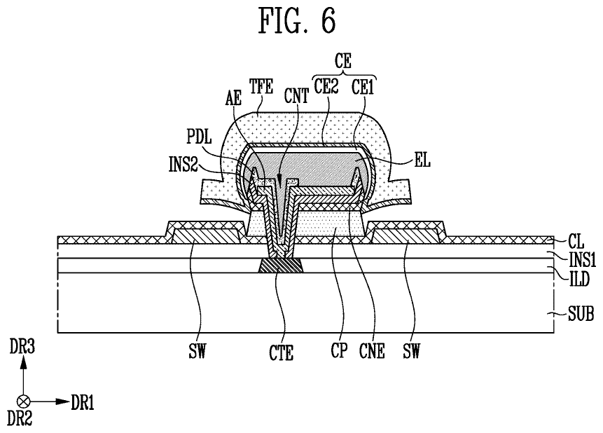

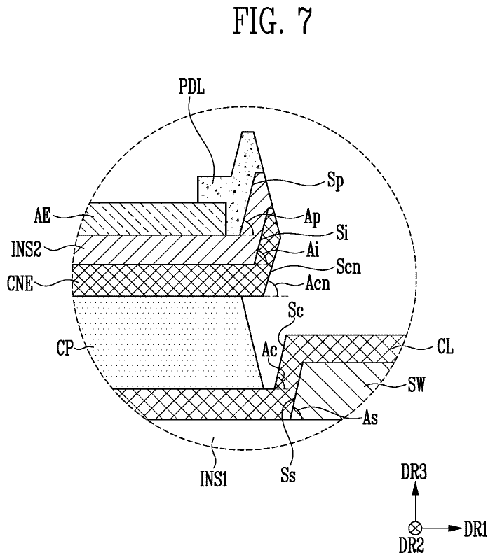

FIGS. 5 and 6 are cross-sectional views illustrating an embodiment of any one of the sub-pixels of FIG. 4. FIG. 7 is an enlarged cross-sectional view illustrating the region A of FIG. 5. FIG. 5 illustrates the light-emitting region EMA of the sub-pixels SP1 to SP3 as a center, and FIG. 6 illustrates the contact portion CNT of the sub-pixels SP1 to SP3 as a center.

Referring to FIGS. 5 to 7, the substrate SUB may include a base layer and a circuit layer. The base layer may be formed of polyimide (PI), glass, a silicon wafer, or the like. The circuit layer may include conductive patterns and insulating layers, and the conductive patterns can function as a sub-pixel circuit (see SPC in FIG. 2) and various wirings. The circuit layer may include circuit elements including transistors and at least one capacitor. Each transistor may include a semiconductor portion including a source region, a drain region, and a channel region, and a gate electrode overlapped with the semiconductor portion. Each capacitor may include electrodes spaced apart from each other in the third direction DR3, with an insulating layer between the electrodes. Wirings of the circuit layer may include signal lines, for example, a gate line, a light-emitting control line, a data line, and the like.

A contact electrode CTE may be disposed on the substrate SUB. The contact electrode CTE may be electrically connected to circuit elements of the circuit layer of the substrate SUB.

An interlayer insulating layer ILD may be disposed on the contact electrode CTE. The interlayer insulating layer ILD may include a contact hole at least partially exposing the contact electrode CTE. The interlayer insulating layer ILD may include an organic material. As an example, the interlayer insulating layer ILD may include, but is not necessarily limited to, at least one of an acrylic resin, a methacrylic resin, polyisoprene, a vinyl resin, an epoxy resin, a urethane resin, a cellulose resin, a siloxane resin, a polyimide resin, a polyamide resin, and a perylene resin.

The interlayer insulating layer ILD may include a first insulating layer INS1. The first insulating layer INS1 may include an inorganic material. As an example, the first insulating layer INS1 may include, but is not necessarily limited to, at least one of silicon nitride (SiNx), silicon oxide (SiOx), silicon oxynitride (SiOxNy), aluminum oxide (AlxOy), titanium oxide (TiOx), tantalum oxide (TaxOy), hafnium oxide (HfOx), and zinc oxide (ZnOx).

A partition wall SW may be disposed on the first insulating layer INS1. The partition wall SW may be disposed directly on the first insulating layer INS1. The partition wall SW may surround the connection electrode CNE. The partition wall SW may surround the light-emitting regions EMA1 to EMA3 and the contact portion CNT.

The partition wall SW may include a first inclined surface Ss. In an embodiment, the inclination angle As of the first inclined surface Ss may range from 30° and 60°. Here, the inclination angle As of the first inclined surface Ss means an angle formed between the upper surface of the first insulating layer INS1 under the partition wall SW (or a plane parallel to an upper surface of the substrate SUB) and the first inclined surface Ss. In an example case in which the inclination angle As of the first inclined surface Ss is formed to be smaller than 30°, the cathode electrode CE to be described later may be disconnected. In an example case in which the inclination angle As of the first inclined surface Ss is larger than 60°, such an inclination angle As may prevent the light-emitting layer EL to be described later from being spaced apart from another light emitting layer.

The partition wall SW may include an inorganic material. As an example, the partition wall SW may include, but is not necessarily limited to, at least one of silicon nitride (SiNx), silicon oxide (SiOx), silicon oxynitride (SiOxNy), aluminum oxide (AlxOy), titanium oxide (TiOx), tantalum oxide (TaxOy), hafnium oxide (HfOx), and zinc oxide (ZnOx). In an embodiment, the partition SW may include the same material as the first insulating layer INS1. As an example, the partition wall SW and the first insulating layer INS1 may be formed of silicon nitride (SiNx).

A connection line CL can be arranged on the first insulating layer INS1 and/or the partition wall SW. The connection line CL may be disposed directly on the first insulating layer INS1. The connection line CL may be disposed directly on the partition wall SW. The connection line CL may entirely cover the partition wall SW. As an example, the connection line CL may directly cover the first inclined surface Ss and the upper surface of the partition wall SW. The connection line CL may be formed along a step of the first inclined surface Ss of the partition wall SW. As an example, the connection line CL may include a second inclined surface Sc corresponding to the first inclined surface Ss of the partition wall SW. The second inclined surface Sc of the connection line CL may be formed along an inclination of the first inclined surface Ss of the partition wall SW. The second inclined surface Sc of the connection line CL may be located above the first inclined surface Ss of the partition wall SW. The second inclined surface Sc of the connection line CL may face the first inclined surface Ss of the partition wall SW.

In an embodiment, the inclination angle Ac of the second inclined surface Sc may be the same as the inclination angle As of the first inclined surface Ss. The inclination angle Ac of the second inclined surface Sc may range from 30° to 60°. Here, the inclination angle Ac of the second inclined surface Sc means an angle formed by a plane parallel to the upper surface of the first insulating layer INS1 under the partition wall SW (or a plane parallel to an upper surface of the substrate SUB) and the second inclined surface Sc. In an example case in which the inclination angle Ac of the second inclined surface Sc is formed to be smaller than 30°, the cathode electrode CE to be described later may be disconnected. In an example case in which the inclination angle Ac of the second inclined surface Sc is larger than 60°, such an inclination angle Ac may prevent the light-emitting layer EL to be described later from being spaced apart from another light emitting layer. In an embodiment, the connection line CL may be formed of, but is not necessarily limited to, titanium (Ti).

A connection pattern CP can be arranged on the connection line CL. The connection pattern CP may be disposed directly on the connection line CL. The connection pattern CP may be disposed between the connection line CL and the connection electrode CNE. The connection pattern CP may be electrically connected with the connection line CL and/or the connection electrode CNE. The connection pattern CP may be surrounded by a partition wall SW. In an embodiment, the connection pattern CP may be formed of aluminum (Al), but is not necessarily limited thereto.

A connection electrode CNE may be disposed on the connection pattern CP. The connection electrode CNE may be disposed directly on the connection pattern CP. The connection electrode CNE may be electrically connected with the connection pattern CP. The width of the connection electrode CNE in the first direction DR1 may be greater than the width of the connection pattern CP in the first direction DR1. As an example, an edge of the connection electrode CNE may protrude beyond an edge of the connection pattern CP. Thus, the connection electrode CNE may form a tip structure protruding from the connection pattern CP.

An edge of the connection electrode CNE may protrude upward. In an example, the connection electrode CNE may include a flat central portion, and an edge of the connection electrode CNET may protrude upward from the central portion. The edge of the connection electrode CNE may have an upwardly inclined shape.

The connection electrode CNE may be surrounded by a planar partition wall SW. An edge of the connection electrode CNE may be formed along a step of the first inclined surface Ss of the partition wall SW. As an example, the edge of the connection electrode CNE may include a third inclined surface Scn corresponding to the first inclined surface Ss of the partition wall SW and/or the second inclined surface Sc of the connection line CL. The third inclined surface Scn of the connection electrode CNE can be formed along the inclination of the first inclined surface Ss of the partition wall SW and/or the second inclined surface Sc of the connection line CL. The third inclined surface Scn of the connection electrode CNE may be located above the first inclined surface Ss of the partition wall SW and/or the second inclined surface Sc of the connection line CL The third inclined surface Scn of the connection electrode CNE may face the first inclined surface Ss of the partition wall SW and/or the second inclined surface Sc of the connection line CL.

In an embodiment, the inclination angle Acn of the third inclined surface Scn may be the same as the inclination angle As of the first inclined surface Ss and/or the inclination angle Ac of the second inclined surface Sc. The inclination angle Acn of the third inclined surface Scn may range from 30° to 60°. Here, the inclination angle Acn of the third inclined surface Scn means an angle formed by a plane parallel to the upper surface of the first insulating layer INS1 under the partition wall SW (or a plane parallel to an upper surface of the substrate SUB) and the third inclined surface Scn. In an example case in which the inclination angle Acn of the third inclined surface Scn is formed to be smaller than 30°, the cathode electrode CE to be described later may be disconnected. In an example case in which the inclination angle Acn of the third inclined surface Scn is larger than 60°, such an inclination angle Acn may prevent the light-emitting layer EL to be described later from being spaced apart from another light emitting layer.

The connection electrode CNE may include the same material as the connection line CL. As an example, the connection electrode CNE and the connection line CL may be formed of titanium (Ti), but are not necessarily limited thereto.

The first insulating layer INS1, the connection line CL, the connection pattern CP, and/or the connection electrode CNE may include a contact portion CNT. The contact portion CNT may penetrate the first insulating layer INS1, the connection line CL, the connection pattern CP, and/or the connection electrode CNE to at least partially expose the contact electrode CTE.

A second insulating layer INS2 may be disposed on the connection electrode CNE. The second insulating layer INS2 may be disposed directly on the connection electrode CNE. The second insulating layer INS2 may be disposed in the contact portion CNT. The second insulating layer INS2 may be at least partially in contact with the first insulating layer INS1, the connection line CL, the connection pattern CP, and/or the connection electrode CNE in the contact portion CNT. The second insulating layer INS2 may include a contact hole at least partially exposing the contact electrode CTE in the contact portion CNT.

In an embodiment, an edge of the second insulating layer INS2 may protrude from an edge of the connection pattern CP. Accordingly, the second insulating layer INS2 can form a tip structure protruding from the connection pattern CP together with the connection electrode CNE.

An edge of the second insulating layer INS2 may protrude upward. As an example, the second insulating layer INS2 may include a flat central portion, and an edge of the second insulating layer 1NS2 may protrude upward from the central portion. An edge of the second insulating layer INS2 may have a shape inclined upward. An edge of the second insulating layer INS2 may surround an anode electrode AE to be described later. In an embodiment, an edge of the second insulating layer INS2 may be spaced apart from an edge of the anode electrode AE, but is not necessarily limited thereto.

The second insulating layer INS2 may be surrounded by the partition wall SW. An edge of the second insulating layer INS2 may be formed along a step of the first inclined surface Ss of the partition wall SW. As an example, the edge of the second insulating layer INS2 may include a fourth inclined surface Si corresponding to the first inclined surface Ss of the partition wall SW, the second inclined surface Sc of the connection line CL, and/or the third inclined surface Scn of the connection electrode CNE. The fourth inclined surface Si of the second insulating layer INS2 may be formed along an inclination of the first inclined surface Ss of the partition wall SW, the second inclined surface Sc of the connection line CL, and/or the third inclined surface Scn of the connection electrode CNE. The fourth inclined surface Si of the second insulating layer INS2 may be located above the first inclined surface Ss of the partition wall SW, the second inclined surface Sc of the connection line CL, and/or the third inclined surface Scn of the connection electrode CNE. The fourth inclined surface Si of the second insulating layer INS2 may face the first inclined surface Ss of the partition wall SW, the second inclined surface Sc of the connection line CL, and/or the third inclined surface Scn of the connection electrode CNE.

In an embodiment, the inclination angle Ai of the fourth inclined surface Si may be equal to the inclination angle As of the first inclined surface Ss, the inclination angle Ac of the second inclined surface Sc, and/or the inclination angle Acn of the third inclined surface Scn. The inclination angle Ai of the fourth inclined surface Si may range from 30° to 60°. Here, the inclination angle Ai of the fourth inclined surface Si means an angle formed by a plane parallel to the upper surface of the first insulating layer INS1 under the partition wall SW (or a plane parallel to an upper surface of the substrate SUB) and the fourth inclined surface Si. In an example case in which the inclination angle Ai of the fourth inclined surface Si is formed to be smaller than 30°, the cathode electrode CE to be described later may be disconnected. In an example case in which the inclination angle Ai of the fourth inclined surface Si is larger than 60°, such an inclination angle Ai may prevent the light-emitting layer EL to be described later from being spaced apart from another light emitting layer.

The second insulating layer INS2 may include an inorganic material. As an example, the second insulating layer INS2 may include, but is not necessarily limited to, at least one of silicon nitride (SiNx), silicon oxide (SiOx), silicon oxynitride (SiOxNy), aluminum oxide (AlxOy), titanium oxide (TiOx), tantalum oxide (TaxOy), hafnium oxide (HfOx), and zinc oxide (ZnOx).

An anode electrode AE (or a first electrode) may be disposed on the second insulating layer INS2. The anode electrode AE may be disposed directly on the second insulating layer INS2. The anode electrode AE may be electrically separated from the connection electrode CNE by the second insulating layer INS2. The anode electrode AE may be electrically connected to the contact electrode CTE through a contact hole of the second insulating layer INS2. The anode electrode AE may be in contact with the contact electrode CTE through a contact hole of the second insulating layer INS2.

A pixel defining layer PDL may be disposed on the second insulating layer INS2 and/or the anode electrode AE. The pixel defining layer PDL may include an opening that at least partially exposes the anode electrode AE. As an example, the pixel defining layer PDL may surround an edge of the anode electrode AE.

In an embodiment, an edge of the pixel defining layer PDL may protrude from an edge of the connection pattern CP. Accordingly, the pixel defining layer PDL can form a tip structure protruding from the connection pattern CP together with the second insulating layer INS2 and/or the connection electrode CNE.

An edge of the pixel defining layer PDL may protrude upward. In an example, the pixel defining layer PDL includes a flat central portion, and an edge of the pixel defining layer PDL may protrude upward from the central portion. An edge of the pixel defining layer PDL may have a shape inclined upward.

The pixel defining layer PDL may be surrounded by the partition wall SW. An edge of the pixel defining layer PDL may be formed along a step of the first inclined surface Ss of the partition wall SW. As an example, the edge of the pixel defining layer PDL may include a fifth inclined surface Sp corresponding to the first inclined surface Ss of the partition wall SW, the second inclined surface Sc of the connection line CL, the third inclined surface Scn of the connection electrode CNE, and/or the fourth inclined surface Si of the second insulating layer INS2. The fifth inclined surface Sp of the pixel defining layer PDL may be formed along the inclination of the first inclined surface Ss of the partition wall SW, the second inclined surface Sc of the connection line CL, the third inclined surface Scn of the connection electrode CNE, and/or the fourth inclined surface Si of the second insulating layer INS2. The fifth inclined surface Sp of the pixel defining layer PDL may be located above the first inclined surface Ss of the partition wall SW, the second inclined surface Sc of the connection line CL, the third inclined surface Scn of the connection electrode CNE, and/or the fourth inclined surface Si of the second insulating layer INS2. The fifth inclined surface Sp of the pixel defining layer PDL may face the first inclined surface Ss of the partition wall SW, the second inclined surface Sc of the connection line CL, the third inclined surface Scn of the connection electrode CNE, and/or the fourth inclined surface Si of the second insulating layer INS2.

In an embodiment, the inclination angle Ap of the fifth inclined surface Sp may be the same as the inclination angle As of the first inclined surface Ss, the inclination angle Ac of the second inclined surface Sc, the inclination angle Acn of the third inclined surface Scn, and/or the inclination angle Ai of the fourth inclined surface Si. An inclination angle Ap of the fifth inclined surface Sp may range from 30° to 60°. Here, the inclination angle Ap of the fifth inclined surface Sp means an angle formed by a plane parallel to the upper surface of the first insulating layer INS1 under the partition wall SW (or a plane parallel to an upper surface of the substrate SUB, and the fifth inclined surface SP. In an example case in which the inclination angle Ap of the fifth inclined surface Sp is formed to be smaller than 30°, the cathode electrode CE to be described later may be disconnected. In an example case in which the inclination angle Ap of the fifth inclined surface Sp is greater than 60°, such an inclination angle Sp may prevent the light-emitting layer EL to be described later from being spaced apart from another light emitting layer.

The light-emitting layer EL may be disposed on the second insulating layer INS2, the pixel defining layer PDL, and/or the anode electrode AE. The light-emitting layers EL of each of the sub-pixels SP1 to SP3 may be spaced apart from one another. As an example, the light-emitting layer EL of each of the sub-pixels SP1 to SP3 may be spaced apart from one another by the tip structure of the pixel defining layer PDL, the second insulating layer INS2, and/or the connection electrode CNE. Accordingly, the light-emitting layers EL of each of the sub-pixels SP1 to SP3 may be spaced apart from each other. The light-emitting layer EL of each of the sub-pixels SP1 to SP3 can generate light of red, green, and blue colors, respectively.

A cathode electrode CE (or a second electrode) may be disposed on the light-emitting layer EL. The cathode electrode CE may be disposed directly on the light-emitting layer EL. The cathode electrode CE may cover the light-emitting layer EL. The cathode electrode CE of each of the sub-pixels SP1 to SP3 may be spaced apart from one another. The cathode electrode CE of each of the sub-pixels SP1 to SP3 may be spaced apart from each other.

The cathode electrode CE may be disposed on the third inclined surface Scn of the connection electrode CNE. The cathode electrode CE may be disposed directly on the third inclined surface Scn of the connection electrode CNE. The cathode electrode CE may cover the third inclined surface Scn of the connection electrode CNE. The cathode electrode CE may be in contact with the third inclined surface Scn of the connection electrode CNE. In this way, when the cathode electrode CE is in contact with the third inclined surface Scn of the connection electrode CNE, the contact area between the cathode electrode CE and the connection electrode CNE is increased, which can reduce the resistance and minimize the risk of disconnection of the cathode electrode CE. According to an embodiment, the cathode electrode CE may be partially in contact with a side surface of the connection pattern CP, but is not necessarily limited thereto.

The cathode electrode CE of each of the sub-pixels SP1 to SP3 may be electrically connected to the connection line CL through the connection electrode CNE. The cathode electrode CE of each of the sub-pixels SP1 to SP3 may be electrically connected to each other via a connection line CL.

The cathode electrode CE may include a transparent conductive material. As an example, the cathode electrode CE may include, but is not necessarily limited to, indium gallium zinc oxide (IGZO).

The cathode electrode CE may include a first electrode layer CE1 and a second electrode layer CE2. The first electrode layer CE1 may be disposed between the light-emitting layer EL and the second electrode layer CE2. The second electrode layer CE2 may be in contact with the third inclined surface Scn of the connection electrode CNE. The second electrode layer CE2 may be at least partially in contact with the connection pattern CP. An edge of the second electrode layer CE2 may extend onto the connection line CL. An edge of the second electrode layer CE2 may be spaced apart from the connection line CL in the third direction DR3. A space may be formed between an edge of the second electrode layer CE2 and the connection line CL.

An encapsulation layer TFE may be disposed on the cathode electrode CE. The encapsulation layer TFE can prevent oxygen, moisture, and the like from penetrating into the light-emitting layer EL and the like. The encapsulation layer TFE may include a structure in which one or more inorganic films and one or more organic films are alternately laminated. The inorganic film may include silicon nitride (SiNx), silicon oxide (SiOx), silicon oxynitride (SiOxNy), or the like. The organic film may include an organic insulating material such as, for example, an acrylic resin, an epoxy resin, a phenol resin, a polyamide resin, a polyimide resin, an unsaturated polyester resin, a polyphenylenether resin, polyphenylenesulfide resin, or benzocyclobutene (BCB). However, the materials of the organic film and the inorganic film of the encapsulation layer TFE are not limited thereto.

According to the above-described embodiment, by forming the inclined surface Scn on the connection electrode CNE by using the partition wall SW, the contact area between the connection electrode CNE and the cathode electrode CE is increased, such that the resistance can be reduced and the risk of disconnection of the cathode electrode (CE) can be minimized.

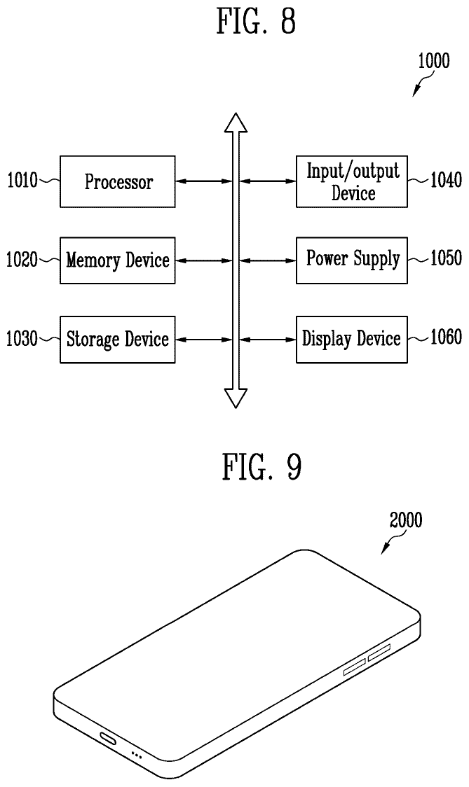

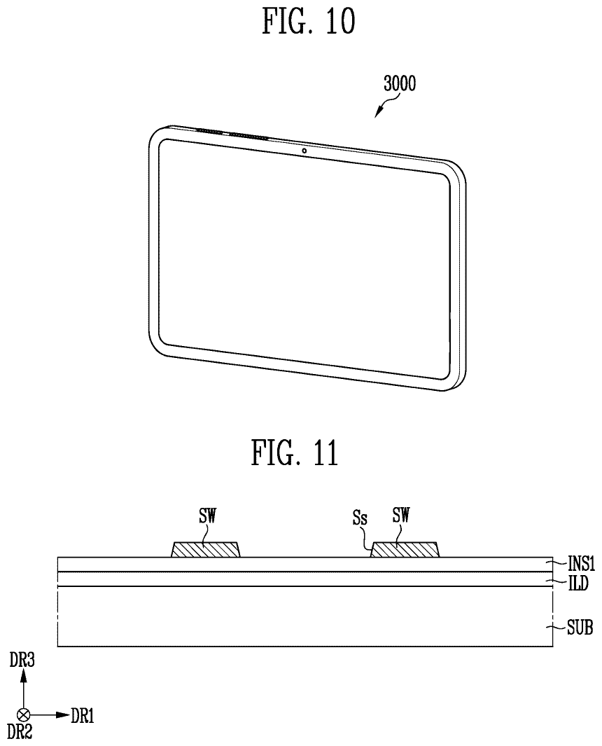

FIG. 8 is a block diagram illustrating an embodiment of a display system including the display device of FIGS. 1 to 7. FIG. 9 is a perspective view illustrating an example of a smartphone that can be implemented using the display system of FIG. 8. FIG. 10 is a perspective view illustrating an example of a tablet computer that can be implemented using the display system of FIG. 8.

Referring to FIG. 8, the display system 1000 may include a processor 1010, a memory device 1020, a storage device 1030, an input/output device 1040, a power supply device 1050, and a display device 1060. The display system 1000 can include the display device 100 in FIGS. 1 to 7 described herein as the display device 1060.

In an embodiment, as illustrated in FIG. 9, the display system 1000 may be implemented as a smartphone 2000. In another embodiment, as illustrated in FIG. 10, the display system 1000 may be implemented as a tablet computer 3000. However, this is an example, and the display system 1000 is not limited thereto. For example, the display system 1000 may be a computer device or an electronic device including the display device 1060, such as, for example, a digital television, a 3D TV, a personal computer, a home electronic device, a laptop, a mobile phone, a video phone, a smart pad, a smart watch, a head mounted display device, a personal digital assistant, a portable multimedia player, a digital camera, a music player, a portable game console, navigation, or the like.

The processor 1010 may perform various tasks and calculations. In an embodiment, the processor 1010 may include an application processor, a graphics processing unit, a microprocessor, a central processing unit (CPU), or the like. The processor 1010 may be connected to other components of the display system 1000 through a bus system. In an embodiment, the bus system may include a peripheral component interconnect (PCI) bus. The processor 1010 can provide a data stream to be displayed on the display device 1060 to the display device 1060. The data stream may be provided to the display device 1060 as the input image data IMG of FIG. 1. The processor 1010 may further transmit the control signal CTRL of FIG. 1 to the display device 1060.

The memory device 1020 may be provided as a working memory and/or a buffer memory of the display system 1000 and/or the processor 1010. In an embodiment, memory device 1020 may include volatile memory devices such as, for example, dynamic random access memory (DRAM), static random access memory (SRAM), mobile DRAM, and so forth.

The storage device 1030 may store data in response to control of the processor 1010. The storage device 1030 may include a nonvolatile storage medium that retains data even when the display system 1000 is powered down. In embodiments, storage device 1030 may include a solid state drive (SSD), a hard disk drive (HDD), and so forth.

Input/output devices 1040 may include user input devices such as, for example, a keyboard, keypad, touchpad, touchscreen, mouse, or the like, and output devices such as, for example, speakers, printers, or the like.

The power supply device 1050 can supply power for the operation of the display system 1000. For example, the power supply device 1050 may be a power management integrated circuit (PMIC). For example, the power supply device 1050 may include a battery.

The display device 1060 may display an image in response to control of the processor 1010. The display device 1060 may be coupled to the other components of the display system 1000 via a bus system and/or other communication link. The display device 1060 can be implemented as the display device 100 in FIG. 1. An image may be displayed on the pixels PXL of the display device 1060, and the sub-pixels SP1 to SP3 of the pixel PXL may be configured as illustrated in FIGS. 4 to 7.

Next, a method for manufacturing the display device according to the above-described embodiment will be described.

FIGS. 11 to 19 are process step-by-step cross-sectional views of a method for manufacturing a display device according to an embodiment. FIGS. 11 to 19 are cross-sectional views for describing a manufacturing method of the display device in FIGS. 1 to 10, which are briefly illustrated and redundant content is omitted for convenience of description.

In the descriptions of the method and processes herein, the operations may be performed in a different order than the order shown and/or described, or the operations may be performed in different orders or at different times. Certain operations may also be left out, one or more operations may be repeated, or other operations may be added. Descriptions that an element “may be disposed,” “may be formed,” and the like include methods, processes, and techniques for disposing the element, forming the element, and the like in accordance with example aspects described herein.

Referring to FIG. 11, the method may include sequentially forming, an interlayer insulating layer ILD, a first insulating layer INS1, and a partition wall SW over a substrate SUB. The interlayer insulating layer ILD can be formed entirely on the substrate SUB. The first insulating layer INS1 may be formed entirely on the substrate SUB. The partition wall SW may be etched to include the first inclined surface Ss. An inclination angle of the first inclined surface Ss of the partition wall SW may range from 30° to 60°. The inclination angle of the first inclined surface Ss of the partition wall SW can be adjusted by the ratio of the etching gas in the process of etching the partition wall SW.

Referring to FIG. 12, the method may include sequentially forming a connection line CL, a connection pattern CP, and/or a connection electrode CNE on the first insulating layer INS1 and the partition wall SW. The connection line CL, the connection pattern CP, and/or the connection electrode CNE may be formed entirely on the substrate SUB.

In an embodiment, the connection line CL may be formed of titanium (Ti), the connection pattern CP may be formed of aluminum (Al), and the connection electrode CNE may be formed of, but not necessarily limited to, titanium (Ti).

The connection line CL, the connection pattern CP, and/or the connection electrode CNE may be formed along a step of the first inclined surface Ss of the partition wall SW As an example, the connection line CL may include a second inclined surface Sc corresponding to the first inclined surface Ss of the partition wall SW. The second inclined surface Sc of the connection line CL may be formed along an inclination of the first inclined surface Ss of the partition wall SW. The second inclined surface Sc of the connection line CL may be located above the first inclined surface Ss of the partition wall SW. The second inclined surface Sc of the connection line CL may face the first inclined surface Ss of the partition wall SW.

The connection electrode CNE may include a third inclined surface Scn corresponding to the first inclined surface Ss of the partition wall SW and/or the second inclined surface Sc of the connection line CL. The third inclined surface Scn of the connection electrode CNE can be formed along the inclination of the first inclined surface Ss of the partition wall SW and/or the second inclined surface Sc of the connection line CL. The third inclined surface Scn of the connection electrode CNE may be located above the first inclined surface Ss of the partition wall SW and/or the second inclined surface Sc of the connection line CL. The third inclined surface Scn of the connection electrode CNE may face the first inclined surface Ss of the partition wall SW and/or the second inclined surface Sc of the connection line CL.

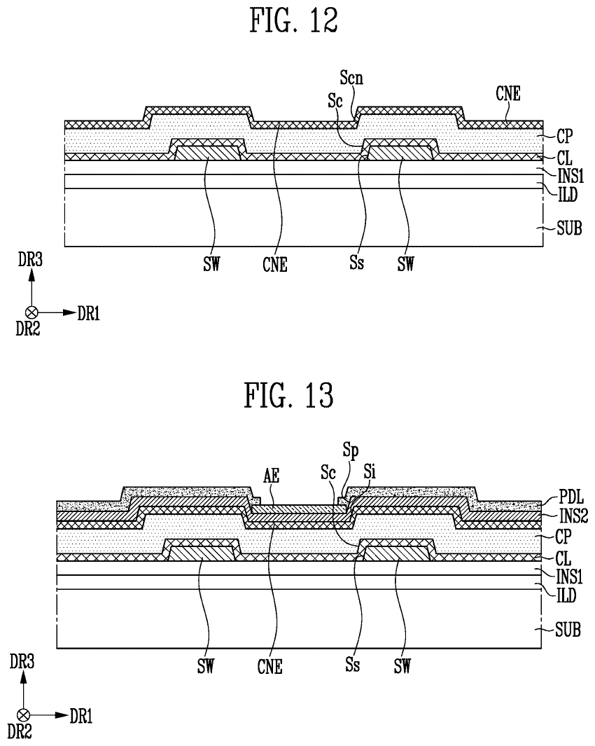

Referring to FIG. 13, then, the method may include sequentially forming the second insulating layer INS2, the anode electrode AE, and/or the pixel defining layer PDL on the connection electrode CNE, and further, etching the pixel defining layer PDL to form an opening portion at least partially exposing the anode electrode AE.

The second insulating layer INS2 and/or the pixel defining layer PDL may be formed along a step of the first inclined surface Ss of the partition wall SW. As an example, the second insulating layer INS2 may include a fourth inclined surface Si corresponding to the first inclined surface Ss of the partition wall SW, the second inclined surface Sc of the connection line CL, and/or the third inclined surface Scn of the connection electrode CNE. The fourth inclined surface Si of the second insulating layer INS2 may be formed along an inclination of the first inclined surface Ss of the partition wall SW, the second inclined surface Sc of the connection line CL, and/or the third inclined surface Scn of the connection electrode CNE. The fourth inclined surface Si of the second insulating layer INS2 may be located above the first inclined surface Ss of the partition wall SW, the second inclined surface Sc of the connection line CL, and/or the third inclined surface Scn of the connection electrode CNE. The fourth inclined surface Si of the second insulating layer INS2 may face the first inclined surface Ss of the partition wall SW, the second inclined surface Sc of the connection line CL, and/or the third inclined surface Scn of the connection electrode CNE.

The pixel defining layer PDL may include a fifth inclined surface Sp corresponding to the first inclined surface Ss of the partition wall SW, the second inclined surface Sc of the connection line CL, the third inclined surface Scn of the connection electrode CNE, and/or the fourth inclined surface Si of the second insulating layer INS2. The fifth inclined surface Sp of the pixel defining layer PDL may be formed along the inclination of the first inclined surface Ss of the partition wall SW, the second inclined surface Sc of the connection line CL, the third inclined surface Scn of the connection electrode CNE, and/or the fourth inclined surface Si of the second insulating layer INS2. The fifth inclined surface Sp of the pixel defining layer PDL may be located above the first inclined surface Ss of the partition wall SW, the second inclined surface Sc of the connection line CL, the third inclined surface Scn of the connection electrode CNE, and/or the fourth inclined surface Si of the second insulating layer INS2. The fifth inclined surface Sp of the pixel defining layer PDL may face the first inclined surface Ss of the partition wall SW, the second inclined surface Sc of the connection line CL, the third inclined surface Scn of the connection electrode CNE, and/or the fourth inclined surface Si of the second insulating layer INS2.

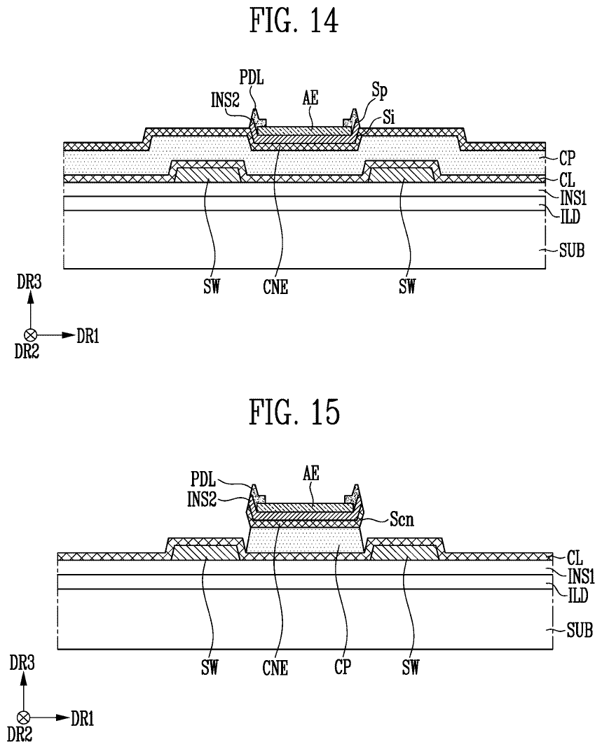

Referring to FIG. 14, the method may include partially etching the pixel defining layer PDL and the second insulating layer INS2. The pixel defining layer PDL and the second insulating layer INS2 may be etched at the same time in the same process. As an example, the pixel defining layer PDL may be partially etched along the edge of the fifth inclined surface Sp of the pixel defining layer PDL. That is, a peripheral region of the fifth inclined surface Sp of the pixel defining layer PDL may be partially etched. The second insulating layer INS2 may be partially etched along an edge of the fourth inclined surface Si. That is, the peripheral region of the fourth inclined surface Si of the second insulating layer INS2 may be partially etched. As the pixel defining layer PDL and the second insulating layer INS2 are partially etched, the connection electrode CNE disposed thereunder may be exposed.

Referring to FIG. 15, the method may include partially etching the connection electrode CNE and the connection pattern CP. The connection electrode CNE may be partially etched, except for a region of the connection electrode which overlaps with the pixel defining layer PDL and/or the second insulating layer INS2. For example, the connection electrode may be partially etched along the edge of the third inclined surface Scn of the connection electrode CNE. That is, a peripheral region of the third inclined surface Scn of the connection electrode CNE may be partially etched.

The connection pattern CP may be etched such that a width of the connection pattern CP in the first direction DR1 is smaller than a width of the connection electrode CNE in the first direction. For example, an edge of the connection pattern CP may be disposed inside an edge of the connection electrode CNE. Thus, the connection electrode CNE may form a tip structure protruding from the connection pattern CP.

The third inclined surface Scn of the connection electrode CNE may be exposed as the connection electrode CNE and the connection pattern CP are etched. In some aspects, as the connection electrode CNE and the connection pattern CP are partially etched, the connection line CL disposed at the bottom may be exposed.

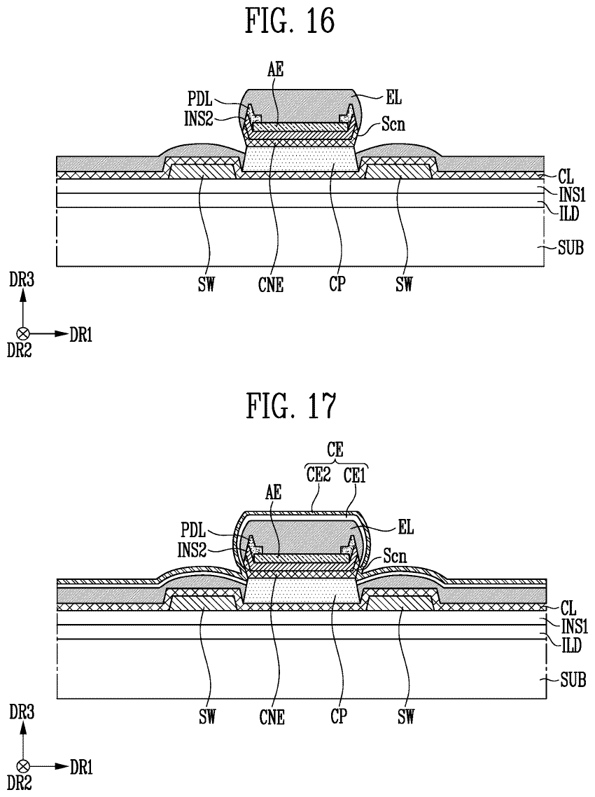

Referring to FIG. 16, the method may include forming a light-emitting layer EL. The light-emitting layer EL may be formed entirely on the substrate SUB. The light-emitting layer EL may be formed on the pixel defining layer PDL, the anode electrode AE, and/or the connection line CL. The light-emitting layer EL formed on the pixel defining layer PDL and the anode electrode AE and the light-emitting layer formed on the connection line CL can be spaced apart from one another. As an example, the light-emitting layer EL formed on the pixel defining layer PDL and the anode electrode AE and the light-emitting layers EL formed on connection lines CL may be separated and spaced from each other by the third inclined surface Scn (or the tip structure) of the connection electrode CNE.

Referring to FIG. 17, the method may include forming a cathode electrode CE. The cathode electrode CE may be formed entirely on the substrate SUB. The cathode electrode CE may be formed on the light-emitting layer EL. Further, the cathode electrode CE may be formed on the third inclined surface Scn of the connection electrode CNE. In an embodiment, the first electrode layer CE1 and the second electrode layer CE2 of the cathode electrode CE may be sequentially formed on the light-emitting layer EL and the connection electrode CNE.

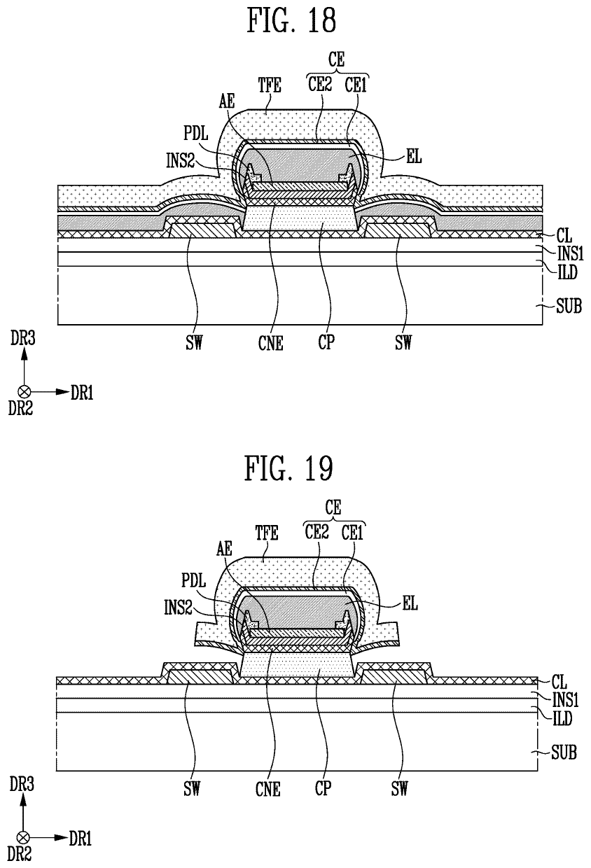

Referring to FIG. 18, the method may include forming an encapsulating layer TFE on the cathode electrode CE. The encapsulation layer TFE may be formed entirely on substrate SUB.

Referring to FIG. 19, the method may include partially etching the encapsulation layer TFE and the cathode electrode CE. The cathode electrode CE and the encapsulation layer TFE except for the region formed on the anode electrode AE and the light-emitting layer EL may be partially etched. In an embodiment, the light-emitting layer EL formed between the cathode electrode CE and the connection line CL may be removed. In this case, a space may be formed between the cathode electrode CE and the connection line CL.

Although specific embodiments have been described herein, other embodiments and variations can be derived from the above description. Accordingly, the spirit of the invention is not limited to the example embodiments, but extends to the claims set forth below, as well as various obvious modifications and equivalents.

What is claimed is:

1. A display device comprising:
a partition wall on a substrate and comprising a first inclined surface;
a connection electrode on the partition wall and comprising a second inclined surface;
a first electrode on the connection electrode;
a light-emitting layer on the first electrode; and
a second electrode on the light-emitting layer and in contact with the second inclined surface of the connection electrode,
wherein the partition wall surrounds the connection electrode in a plan view.

2. The display device of claim 1, further comprising a connection line on the partition wall.

3. The display device of claim 2, wherein the connection line is directly on the partition wall.

4. The display device of claim 2, wherein the connection line entirely covers the partition wall.

5. The display device of claim 2, further comprising a connection pattern between the connection line and the connection electrode.

6. The display device of claim 5, wherein the connection pattern is electrically connected to the connection line and the connection electrode.

7. The display device of claim 5, wherein a width of the connection pattern is less than a width of the connection electrode.

8. The display device of claim 1, further comprising a contact electrode on the substrate and electrically connected to the first electrode.

9. The display device of claim 8, further comprising a first insulating layer on the contact electrode.

10. The display device of claim 9, wherein the partition wall is directly on the first insulating layer.

11. The display device of claim 10, wherein the partition wall comprises a same material as the first insulating layer.

12. The display device of claim 8, wherein the first electrode is in contact with the contact electrode through a contact portion which penetrates through the connection electrode.

13. An electronic device comprising:
a processor; and
a display device comprising pixels, wherein the display device displays an image via the pixels under control of the processor,
wherein the pixels each comprise:
a partition wall on a substrate and comprising a first inclined surface;
a connection electrode on the partition wall and comprising a second inclined surface;
a first electrode on the connection electrode;
a light-emitting layer on the first electrode; and
a second electrode on the light-emitting layer and in contact with the second inclined surface of the connection electrode,
wherein an inclination angle of the first inclined surface is the same as an inclination angle of a second inclined surface.

14. The electronic device of claim 13, wherein an inclination angle of the first inclined surface and an inclination angle of a second inclined surface range from 30° to 60°.

15. The electronic device of claim 13, further comprising a second insulating layer between the connection electrode and the first electrode.

16. The electronic device of claim 15, wherein the second insulating layer comprises a third inclined surface.

17. The electronic device of claim 16, wherein an inclination angle of the third inclined surface is the same as the inclination angle of the first inclined surface.

18. The electronic device of claim 13, further comprising a pixel defining layer surrounding an edge of the first electrode.

19. The electronic device of claim 18, wherein the pixel defining layer comprises a fourth inclined surface.

20. The electronic device of claim 19, wherein an inclination angle of the fourth inclined surface is the same as the inclination angle of the first inclined surface.
